(19) United States
(12) Patent Application Publication
(10) Pub. No.: US 2003/0164490 A1
(43) Pub. Date: Sep. 4, 2003

(54) Optimization method for quantum computing process

(76) Inventor: Alexandre Blais, Sherbrooke (CA)

Correspondence Address: GARY S. WILLIAMS, PENNIE & EDMONDS LLP, 3300 HILLVIEW AVENUE, PALO ALTO, CA, 94304, US

(21) Appl. No.: 09/782,886

(22) Filed: Feb. 13, 2001

(51) Int. Cl. H01L 29/06; H01L 31/0328

(52) U.S. Cl. 257/14

(57) ABSTRACT

Quantum computing in a one-dimensional array of qubits limited to nearest-neighbor couplings is optimized using reordering of output qubits, reordering of operations, and simultaneous operations. Efficient implementations of logical gates useful for several designs of quantum computers reduce the time required for quantum computations. Taking account of the possibility of performing simultaneous operations on distinct qubits, efficient networks realizing the quantum Fourier transform are presented as illustration of the method.

### COPYRIGHT NOTICE

A portion of the disclosure of this patent document contains material which is subject to copyright protection. The copyright owner has no objection to the facsimile reproduction by anyone of the patent document or the patent disclosure, as it appears in the Patent and Trademark Office patent files or records, but otherwise reserves all copyright rights whatsoever.

### REFERENCE TO APPENDIX ON COMPACT DISC

An Appendix containing a computer program listing is submitted on a compact disc, which is incorporated by reference herein in its entirety. The total number of compact discs including duplicates is two. Each of the compact discs includes a file named “anneal.txt”, which was created Feb. 7, 2001 and has a size of 19,285 bytes and file named “swap.txt”, which was created Feb. 6, 2001 and has a size of 11,791 bytes.

### BACKGROUND

1. Field of the Invention

This invention relates to quantum computing and particularly to methods for reducing the required coherence time in a quantum computer performing a computation such as a quantum Fourier transform or any quantum network.

2. Description of Related Art

Research on what is now called quantum computing traces back to Richard Feynman, (R. Feynman, Int. J. Theor. Phys., 21, 467-488 (1982)). Feynman noted that quantum systems are inherently difficult to simulate with conventional computers but that observing the evolution of a quantum system could provide a much faster way to solve some computational problems.

Quantum computing generally involves initializing the quantum states of a set of qubits (quantum bits), allowing the quantum states of the qubits to evolve under the influence of quantum gates, and reading the qubits after they have evolved. A qubit is conventionally a system having two quantum states (typically two degenerate states), and the state of the qubit typically has non-zero probabilities of being found in either state. N qubits provide a system with state that is a combination of ₂N states. The quantum gates control the evolution of the distinguishable quantum states and define calculations corresponding to the evolution of the quantum state of the system. This evolution, in effect, performs 2^{N} simultaneous calculations. Reading the qubits after evolution determines the states of the qubits and the results of the calculations.

The presentation by Shor (P. W. Shor, “Polynomial-Time Algorithms for Prime Factorisation and Discrete Logarithms on a Quantum Computer,” SIAM J. Comp., 26:1484, 1997) of an efficient quantum process for factorization has kindled great interest in developing of software for quantum computing. In particular, a lot of attention has focused on developing methods for efficient computations and error correction in quantum computers.

In parallel, great effort as been invested in developing physical implementations of quantum computers that meet the very stringent requirements needed for the coherent manipulation of quantum information. The first proposals for such quantum computers were based on trapped ions, cavity quantum electrodynamics systems, and NMR spectroscopy. NMR-based implementations of quantum computers have been successful at least for a limited number of qubits. See E. Knill et al., “An Algorithmic Benchmark for Quantum Processing,” Nature, 404:368 (2000), which is hereby incorporated by reference in its entirety. However, the inherent limitations of NMR-based quantum computers have motivated the search for more scalable designs.

The high level of expertise available in solid-state based technologies establishes solid-state systems as a leading candidate for the realization of a useful (several thousands of qubits) quantum computer. Solid-state quantum computers have been proposed including Josephson junctions, quantum dots, or spin resonance transistors as qubits. Recent experimental success at coherently manipulating a solid-state qubit, for example, as described by Y. Nakamura et al., “Coherent Control of Macroscopic Quantum States in a Single-Cooper Pair Box,” Nature (London), 398:786, 1999, gives good confidences that solid-state quantum computers are practical. However, the large numbers of degrees of freedom in solid-state quantum computers typically cause such quantum computers to suffer from short coherence times. (The coherence time is the time during which a quantum state of the quantum computer can evolve before external influences interfere with the quantum states of the qubits.) To take full advantage of the computational power of a solid-state quantum computer, optimization of the software for the specific quantum hardware will be critical. In particular, optimized software that reduces the total coherence time required for a computation will determine whether the quantum computer can complete a specific calculation.

### SUMMARY

In accordance with the invention, fundamental gates necessary for a quantum Fourier transform and other quantum networks are built from physically realizable operations, each of which takes a specific time to complete. The fundamental gates and swap operations have commutation relationships that permit optimizations in the application of the gates and quantum computation processes employing the gates. In the case of the quantum Fourier transform algorithm, an order O(N²) speedup is obtained over the conventional ordering of the fundamental gates. Such improvements are considerable in the context of the physical realization of quantum algorithms where coherent manipulations are limited to a short coherence time.

One specific embodiment of this invention is a method for reducing required coherence time for a quantum computation. This is accomplished by constructing a second series of operations from a first series by changing the execution order of the commuting operations in a way maximizing the number of operations that can be performed simultaneously. This reduces the time required for a quantum computing device to complete the second series of operations. Changing the execution order of the commuting operations can enable simultaneous execution of operations in the second series and/or can eliminate the need for some swap operations.

In accordance with another aspect of the invention, a method for performing a swap operation in a quantum computing device reduces the required computation time by simultaneously performing fundamental operations that commute.

### BRIEF DESCRIPTION OF THE DRAWINGS

FIG. 1 is a block diagram of a multi-qubit quantum register suitable for computations described further herein.

FIG. 2 illustrates a network realizing a quantum Fourier transform on a 4-qubit register.

FIGS. 3A and 3B respectively illustrate use of sequential and simultaneous swap operations to provide controlled interactions between non-adjacent qubits.

FIG. 4 illustrates a network performing a quantum Fourier transform using a 4-qubit register and simultaneous operations including swap operations.

FIG. 5 illustrates a quantum Fourier transform network for an array of four qubits allowing for nearest-neighbor interactions and simultaneous operations.

FIG. 6 illustrates a process for constructing an improved quantum Fourier transform network for any number of qubits.

FIG. 7 illustrates a further optimization of a network for a quantum Fourier transform.

FIG. 8 is a graph comparing the time costs of conventional quantum computing processes and optimized quantum computing process in accordance with the invention.

Use of the same reference symbols in different figures indicates similar or identical items.

### DETAILED DESCRIPTION

In accordance with an aspect of the invention, a one-dimensional array of qubits that allows for nearest-neighbor interactions performs simultaneous operations on distinct qubits and thereby shortens the time required for quantum networks such as quantum Fourier transforms. For illustrative purposes, a particular solid-state quantum register suitable for implementation of quantum computational processes in accordance with the invention is described below. However, such quantum computational processes as described herein can be implemented in other quantum computing structures including other solid-state quantum registers that exist or may be developed and other types of quantum computers such as the NMR-based systems.

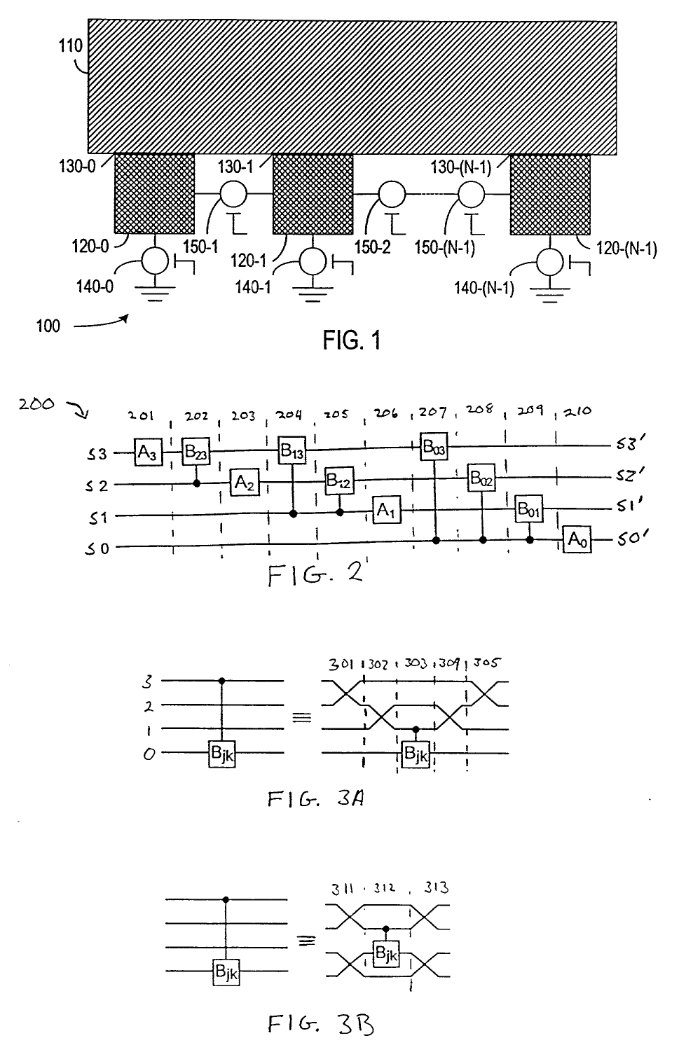

FIG. 1 illustrates an example of a solid-state multi-qubit register 100 containing a linear array of qubits. Quantum registers such as register 100 are further described in co-owned U.S. patent app. Nos. 09/452,749 and 09/479,336, which are hereby incorporated by reference in their entirety. Register 100 includes qubits based on Josephson junctions 130-0 to 130-(N−1) that are at the interfaces between a superconducting bank 110 and respective mesoscopic, superconducting islands 120-0 to 120-(N−1). A d-wave superconductor, for example, a high-Tc superconductor such as YBa₂Cu₃O₇₋ₓ or any superconductor, in which the Cooper pairs are in a state with non-zero orbital angular momentum makes up one or both of bank 110 and islands 120-0 to 120-(N−1).

A Josephson junction having a d-wave superconductor on one or both sides has ground state current that is doubly degenerate. In particular, the ground state current at each of the Josephson junctions 130-0 to 130-(N−1) is non-zero and either clockwise or counter-clockwise. The ground state current at the ith Josephson junction has two basis quantum states |CWi> and |CCWi> respectively corresponding to clockwise and counterclockwise currents. Generally, each qubit is in a ground state that is a linear combination of the current states. For example, a state of the first qubit is a combination a*|CW0>+b*|CCW0>, where a and b are complex numbers. The two basis states |CWi> and |CCWi>, for each value i from 0 to (N−1), can be arbitrarily assigned respective binary values 0 and 1.

The quantum state of register 100, which is the combination of N qubit states, is represented as |N−1, . . . , 0>. State |N−1, . . . , 0>has 2^{N} different ground state current configurations according to whether the current at each qubit is clockwise or counterclockwise, but generally state |N−1, . . . , 0>is a combination of the different current states and does not have a definite current configuration. The N-qubit states having definite current configurations (and therefore corresponding to definite binary values) are designated herein as |x> or |y>, where x and y are N-bit binary values between 0 and 2^{N}−1. Accordingly, Equation 1 gives a general representation of the state |N−1, . . . , 0>.

$$Equation 1 : \\ \vert N - 1 , … , 0 ⟩ = {\sum }_{y = 0}^{{2}^{N} - 1} {a}_{y} \vert y ⟩$$

In Equation 1, coefficients a_{y} are generally complex numbers.

For calculations, register 100 is cooled to a low temperature (e.g., less than about 10° K) to make bank 110 and islands 120-0 to 120-(N−1) superconductive and to suppress thermal sources of decoherence that would disturb the states of the qubits. Initial states of the qubits are then established, for example, by passing a current through bank 110. The initial state depends on the direction of current in bank 110, the crystal orientations of bank 110 and islands 120-0 to 120-(N−1), the nature and shape of the interface between bank 110 and islands 120-0 to 120-(N−1), and any externally applied magnetic fields.

Another way to initialize a qubit is to measure the state, i.e., determine whether the current at the junction is clockwise or counterclockwise. The measurement forces the qubit into a definite state corresponding to the measured value. If the measurement provides the desired result, the computation can start. If the desired state was not obtained, a NOT gate applied to the qubit can invert the qubit's state, and then a subsequent measurement acts as a kind of error correction to ensure that the NOT gate was realized correctly. To perform a useful computation, the initial state must be known and typically has a definite binary value. Usually, the initial state is chosen to have the binary value 0, that is, all qubits are in state corresponding to 0.

The quantum calculation is performed as the initial state evolves under the influence of various interactions on the states. These interactions are commonly referred to as quantum gates. In quantum register 100, single electron transistors (SETs) 150-2 to 150-N are between neighboring islands 120-1 to 120-N. When SETs 150-2 to 150-N are off, the states |0> to |N−1> of the qubits evolve separately. When one or more SETs 150-2 to 150-N are on, SETs 150-2 to 150-N create controllable entanglements of the quantum states of neighboring qubits. Register 100 is one-dimensional in that entanglements can only be created between neighboring qubits along a single line.

When the quantum calculation is complete, the current states of the qubits are observed or read to determine results. For reading the results, SETs 140-0 to 140-(N−1), which are between ground and respective islands 120-0 to 120-(N−1), can be turned on to “freeze” the respective current states of the qubits. The current states of the qubits can then be determined with a measuring device (not shown). A magnetic force microscope (MFM) tip or a superconducting quantum interferometer device (SQUID) loop, for example, can measure the magnetic moments at the individual Josephson junctions to determine the current states.

A limitation of a quantum register is the coherence time of the qubits. The coherence time generally indicates the time during which the quantum state of a qubit can evolve before external factors disrupt the quantum state. A quantum calculation must be completed with the coherence time. Accordingly, one goal of quantum computing is to minimize the time costs of the process or network that performs a quantum calculation.

One useful quantum calculation is a quantum Fourier transform. The quantum Fourier transform is a quantum generalization of the classical Fourier transform. In the field of quantum computing, quantum Fourier transforms are the basis for most know quantum computations. In particular, quantum Fourier transforms are used in Shor's factorization algorithm (and were developed by Shor for this very purpose). The quantum Fourier transform acts on the state |N−1, . . . , 0> of an N-qubit register as shown in Equation 2.

$$Equation 2 : \\ {QFT}_{N} : \vert x ⟩ -> \frac{1}{{2}^{N / 2}} {\sum }_{y = 0}^{{2}^{N} - 1} {ⅇ}^{2 πi \frac{xy}{{2}^{″}}} \vert y ⟩$$

In Equation 2, state |x> and each state |y> has definite current configuration (i.e., correspond to definite N-bit values x and y), and the summation over states |y> is a summation over all definite current states (i.e., all N-bit values y). The quantum Fourier transformation of Equation 2 can be performed on a N-qubit register 100 using two basic quantum gates: a one-qubit gate Aᵢ acting on the state initially corresponding to the ith qubit and a two-qubit gate Bⱼₖ acting on the states initially jth and kth qubits.

The one-qubit gate Aᵢ (also known as the Hadamard transformation) is shown in Equation 3.

$${A}_{i} = \frac{1}{\sqrt{2}} ( \begin{matrix}1 & 1 \\ 1 & - 1\end{matrix} ) \qquad Equation 3 :$$

In Equation 3, the basis vectors for the operator are the two basis states |CWᵢ> or (0 1) and |CCWi> or (1 0) of the ith qubit. The one-qubit gate can be implemented in quantum register 100 as described below.

Equation 4 corresponds to the two-qubit gate Bⱼₖ.

$$Equation 3 : \\ {B}_{jk} = ( \begin{matrix}1 & & & \\ & 1 & & \\ & & 1 & \\ & & & {ⅇ}_{j k}^{ⅈ θ}\end{matrix} )$$

In Equation 4, the basis vectors for the operator are the four basis states created from the cross product of the basis states |CWj> and |CCWj> of the jth qubit with the basis states |CWk> and |CCWk> of the kth qubit. Coefficients j and k specify the pair of qubits on which to apply the quantum gate Bⱼₖ. The angle θjk is defined as π/2^{k-j} and so is determined by the “distance” between the qubits on which quantum gate Bⱼₖ is applied. The two-qubit gate Bjk can be implemented in quantum register 100 as described further below.

Equation 5 indicates a sequence of quantum gates that when implemented in a 4-qubit register, performs the quantum Fourier transform of Equation 1 on the state of the quantum register.

QFT₄=A₃B₂₃A₂B₁₃B₁₂A₁B₀₃B₀₂B₀₁A₀ Equation 5:

FIG. 2 illustrates the quantum network 200 corresponding to Equation 5 and specifically illustrates the quantum gates acting on particular qubits. This quantum Fourier transform on a four-qubit register thus uses ten quantum gates, but more generally, computing an N-qubit quantum Fourier transform QFTN uses N one-qubit operations and N(N−1)/2 two-qubit operations. The ten quantum gates act on respective qubits during ten time intervals 201 to 210. As described further below, the intervals 201 to 210 are generally not equal in duration. The duration of each of intervals 201 to 210 depends on the associated quantum gate and the underlying quantum register implementing the associated gate.

Optimizing a given computational process generally requires expressing the computational process in terms of the elementary set of gates of the quantum architecture in use. For example, Equations 6, 7, and 8 provide a universal set of operators X(θ), Z(φ), and CP(ζ).

$$Equation 6 : \\ X ( θ ) = {ⅇ}^{\frac{- {ⅈσ}_{x} θ}{2}} \\ Equation 7 : \\ Z ( φ ) = {ⅇ}^{\frac{- ⅈ {σ}_{z} φ}{2}} \\ Equation 8 : \\ CP ( ) = {ⅇ}^{\frac{- ⅈ {σ}_{z} ⊗ {σ}_{z} }{2}}$$

In Equations 6, 7, and 8, σₓ and σ_{z} are Pauli matrices. Operators X(θ) and Z(φ) are single qubit operators and can be indexed according to the qubit operand. Operator CP(ζ) is a two qubit operator and require a pair of indices to identify the qubit operands.

Operators X(θ), Z(φ), and CP(ζ) correspond to the elementary set of gates of many solid-state designs and can be implemented in NMR-based quantum computers. See N. A. Gershenfeld and I. L. Chuang, “Bulk Spin-Resonance Quantum Computation,” Science, 275:351, 1997. Implementation of Operators X(θ), Z(φ), and CP(ζ) in a quantum register such as illustrated in FIG. 1 is described in the paper of A. Zagoskin and A. Blais, “Operation of universal gates in a solid-state quantum computer based on clean Josephson junctions between d-wave superconductors' Phys. Rev. A 61 :042308 (2000)” which is hereby incorporated by reference in its entirety.

The elementary operations X(θ), Z(φ), and CP(ζ) implement the gate Bjk (on two adjacent qubits j and k) and the gate s Aj (on qubit j) as indicated in Equations 9 and 10.

Aⱼ=iZⱼ(π/2)Xⱼ(π/2)Zⱼ(π/2) Equation 9:

Bⱼₖ=e^{iθ}^{ₖ₋ⱼ₊₁}Zⱼ(θₖ₋ⱼ₊₁)Zₖ(θₖ₋ⱼ₊₁)CPⱼₖ(θₖ₋ⱼ₊₁) Equation 10:

In Equation 10, the phase exp{iθₖ₋ⱼ₊₁} depends on which qubits j and k are the operands of operator Bjk but is independent of the states of qubits j and k. The phase exp{iθₖ₋ⱼ₊₁} is thus an unimportant global phase factor and can be ignored.

The network of FIG. 2 requires applying gate Bjk to nonadjacent qubits. However, a one-dimensional array of qubits generally limits interaction between qubits to nearest-neighbor couplings, e.g., in quantum register 100 of FIG. 1, each of SETs 130-1 to 130-(N−1) creates controlled a entanglement between two adjacent qubits. Accordingly, applying gate Bjk to nonadjacent qubits entails swapping recursively the states of adjacent qubits so that the states move to adjacent qubits for interaction.

Quantum bits initially at locations j and k require |j−k|−1 swap operations to bring the qubits together and another |j−k|−1 swap operations to return the quantum bits to their original locations. For example, FIG. 3A shows a network implementing Bⱼₖ when j is 0 and k is 3. Two swaps during time intervals 301 and 302 bring the state from qubit 3 to qubit 1, which is adjacent to qubit 0. The quantum gate B is during time 303 while the states are in adjacent qubits, then two swaps during times 304 and 305 return the evolved state from qubit 1 to qubit 3.

A swap SWᵣₛ between qubits at positions r and s respectively is usually realized by a sequence of controlled-NOT (CN) gates as shown in Equation 11.

SWᵣₛ=CNᵣₛCNₛᵣCNᵣₛ Equation 11:

In accordance with an aspect of the invention, the CN gate can be realized by a sequence of 7 elementary gates as shown in Equation 12.

CNᵣₛ=e^{-i3π/4}Xₛ(3π/2)CPᵣₛ(π/2)Zₛ(π/2)Xₛ(π/2)Zₛ(π/2)Zᵣ(π/2)CPᵣₛ(π/2)

As a result, a single swap operation SWᵣₛ requires 21 elementary gates (time steps). This sequence in Equation 12 is shorter than that normally used for a CN gate. The main difference between Equation 12 and prior proposals is the use of two 2-qubit gates (CP) instead of one to realize the CN gate.

The number of elementary operations required for a swap can be significantly reduced using the commutation relations between the elementary gates and the symmetry of the Controlled-NOT gate. More particularly, removing redundant gates can reduce the number of time steps for the sequence of Equation 11. Equation 13 indicates a swap sequence implemented in 15 elementary operations.

SWᵣₛ=e^{-iπ/4}Xₛ(3π/2)CPᵣₛ(π/2)Zₛ(π/2)Xₛ(π/2)[Zₛ(π/2)Xᵣ(π/2)]CPᵣₛ(π/2)Zᵣ(π/2)[Xᵣ(π/2)Xₛ(π/2)]CPᵣₛ(π/2)Zₛ(π/2)Xₛ(π/2)[Zₛ(π/2)Zᵣ(π/2)] Equation 13:

Furthermore, performing operations on different qubits simultaneously further reduces the number of time steps used for moving qubits through the register. Indeed, since operations on distinct qubits commute, the gates in square brackets in Equation 13 can be performed simultaneously, reducing the number of time steps required to complete a swap to twelve.

Further, instead of only swapping qubit j toward qubit k, as in FIG. 3A, simultaneously swapping qubits j and k with their neighbors as in FIG. 3B further reduces the number of time steps. Accordingly, the number of time steps used to juxtapose qubit states initially in the jth and kth qubits and return the interacted states to their original position is reduced to 2_{┌}|j−k|/2_{┐}, where _{┌}x_{┐} is the smallest integer larger than x.

An additional simplification of the computational process is that states of qubits that have been juxtaposed don't have to be moved back to their original location. Instead, once two qubit states have been brought together and interacted, the next reorganization should be done in a way optimizing the realization of the following quantum gates. The location of the qubit states in the quantum register can be tracked classically, and bits can be reorder as required either during the initialization of qubits or when interpreting results read from the quantum register.

The above simplifications of the quantum computation reduces the number of physical time steps from 42(|j−k|−1) to 12_{┌}|j−k|/2_{┐} for a single swap sequence to juxtapose the jth and kth qubits.

FIG. 4 shows an optimized quantum Fourier transform QFT₄ 400 that reduces the number of swap operations in the manner described above. Additionally, the necessary swap operations are optimized using simultaneous swap operations and an efficient reordering of the qubits. In particular, initial states S0, S1, S2, and S3 of respective qubits Q0, Q1, Q2, and Q3 respectively correspond to the resulting states S0′, S1′, S2′, and S3′, which are in qubits Q1, Q2, Q0, and Q3 respectively. The process of FIG. 4 includes ten logical gates and four swaps, which require 54 time steps. In evaluating the time cost of a given quantum network, when simultaneous operations are performed, the number of steps of the most time consuming operation is used. Without optimization, this transformation would require eight swaps in addition to the ten logical gates for a total of 126 physical time steps.

The computational process of FIG. 4 can be further optimized, in terms of the number of time steps, using reordering and simultaneous execution of gates that commute. In particular, 1-qubit gates such as gate Ai commute with the swap operation. The gate Ai is performed on the qubit containing the evolved state originally corresponding to the ith qubit and accordingly may be performed on a different qubit after a swap. A 1-qubit gate can be performed simultaneously with a swap only if both are not acting on the same qubit. A 2-qubit gate Bⱼₖ commutes with a swap only if they are not acting on the same qubit(s). For example, in FIG. 4, operation A₂ is during time interval 403 when the evolved state S2 is the state of the qubit Q2. Accordingly, operation A₂ is performed on qubit Q2. A swap operation during time interval 404 swaps state S1 from qubit Q1 into qubit Q2 and swaps state S2 from qubit Q2 into qubit Q1. As a result, states S3 and S1 will be adjacent in the register for operation B₁₃. By changing the order of application of the swap (interval 404) and A₂ (interval 403), A₂ and B₁₃ can now be performed simultaneously. This is shown in the intervals 503 and 504 of FIG. 5.

Communitivity of other operators permit similar time savings. Specifically, as indicated by the commutators in Equations 14,15, and 16, gate Aᵢ commutes with gate Aⱼ if i is not equal to j, gate Aᵢ commutes with gate Bⱼₖ if i is not equal to j or k, and gate Bⱼₖ commutes with Bᵣₛ for all j, k, r, and s.

| | | |
|---|---|---|
| Equation 14: | [Ai,Aj] = 0 | if i ≠ j |
| Equation 15: | [Ai,Bjk] = 0 | if i ≠ j or k |
| Equation 16: | [Bjk,Brs] = 0 | for all j, k, r, and s. |

These commutation relations allow permutations of the order of the logical operations of the computational process of FIG. 4. For example, in FIG. 4, swap operations during interval 408 put the states evolved from states S0 and S3 in adjacent qubits Q1 and Q2 for operation B₀₃ during interval 409. A subsequent swap during time interval 410 moves the state evolved from S1 into qubit Q2 for operation B₀₁ is during interval 411 after operations B₀₂ and B₀₃. In this ordering of operations, the swap operation of interval 410 undoes one of the swap operations of interval 408.

The process of FIG. 5 places operation B₀₁ before operations B₀₂ and B₀₃ during an interval 507. This reordering eliminates a swap operation because the states evolved from states S0 and S1 are in adjacent qubits Q1 and Q2 for operation B₀₁. Of the swap operations of interval 408 in FIG. 4, the process of FIG. 5 eliminates one and performs the other during interval 506 simultaneously with operation A₁. Accordingly, the reordering further shortens the time required for the process of FIG. 5.

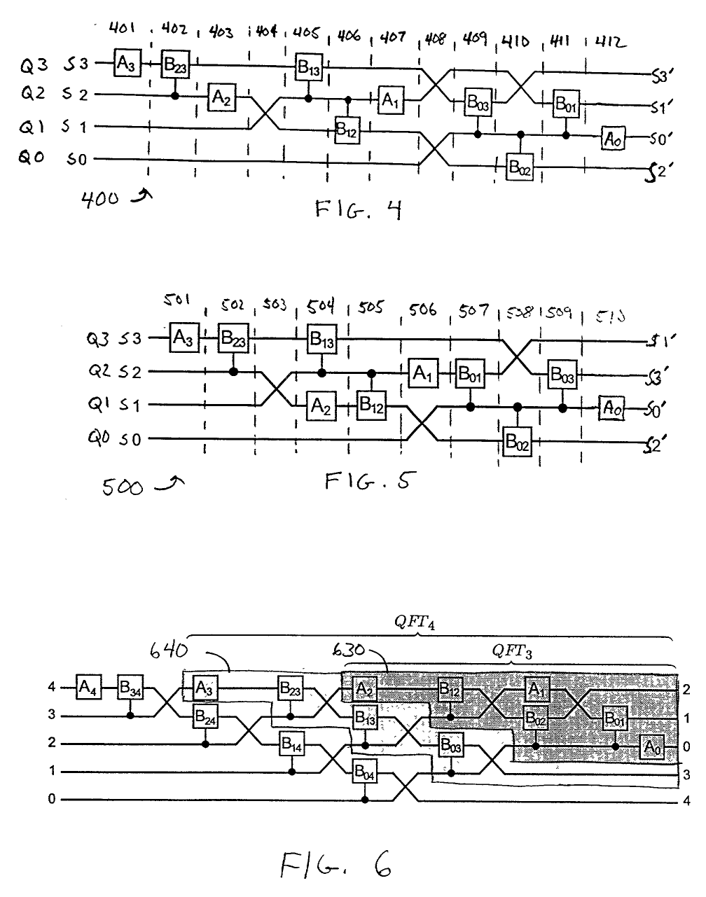

FIG. 6 illustrates a process for constructing an improved network for quantum Fourier transforms (QFT) on n qubits. In FIG. 6, the operations in block 630 implement an efficient QFT on three qubits. Adding four logical gates A₃, B₂₃, B₁₃, and B₀₃ and three swaps to the QFT on three qubits provides a QFT on four qubits, which is contained in block 640. The added gates and swaps that provide the QFT₄ of block 640 add 29 time steps to the QFT₃ of block 630. Adding 5 logical gates A₄, B₃₄, B₂₄, B₁₄, and B₀₄ and four swaps provides a QFT on five qubits. These added gates and swaps add a further 29 time steps.

Using this construction of FIG. 6 recursively on the operation network for QFTₙ₋₁ provides an optimized network for QFTₙ. Constructing QFTₙ from QFTₙ₋₁ requires addition of n logical gates Aₙ₋₁, B_{(n-2),(n-1), . . . B}_{0,(n-1)} and n−1 swaps between qubits n−1 and n−2, qubits n−2 and n−3, . . . and qubits 1 and 0, the swaps being interleaved with the added two qubit operations B. However, the number of added time steps is still 29, and the number of time steps required for this network construction of QFTₙ is 8+29(n−2)(≈O(n))for n>2. The number of time steps required for a straitforward conventional implementation of a network for QFTn is 10n−11n²+4n³ (≈O(n³)). Accordingly, the networks disclosed here provide significant performance gains.

FIG. 8 shows the time cost of quantum Fourier transforms as a function of the number of qubits for up to 300 qubits on a logarithmic scale for both improved networks (black circles) and conventional non-improved networks (open squares). The improved networks were obtained numerically using the method disclosed above. In particular, grouping and parallel execution of operations that commute while not acting on similar qubits can maximize performance of parallel operations to minimize the required time for a given network. Such optimizations can be performed efficiently, taking a fews minutes for a 300 qubits network on a conventional desktop computer. The file “swap.txt” in the CD appendix contains a listing for the program that performs the automated optimization of QFTn.

For very small networks, both curves in FIG. 6 coincide while, for larger networks, it is clear that the numerical data correspond to circuits which are much more efficient. From the logarithmic plot of the numerical data, we obtain a slope of 1.08±0.01 for networks involving more than 10 qubits. This confirms that the quantum Fourier transform can be implemented in O(n) time steps on n quantum bits. This corresponds to a speedup of order O(n²) compared to non-optimized networks. Efficient use of swaps and massive (classical) parallelism are responsible for this speedup. Indeed, speedup by a factor of O(n) can be seen to come from the fact that O(n³) swaps are necessary in non optimized circuits while only O(n²) in the optimized case. The other factor of O(n) comes from the fact that up to n simultaneous operations can be realize on n qubits. As in the case of classical parallel computers, this provides a speedup of order O(n).

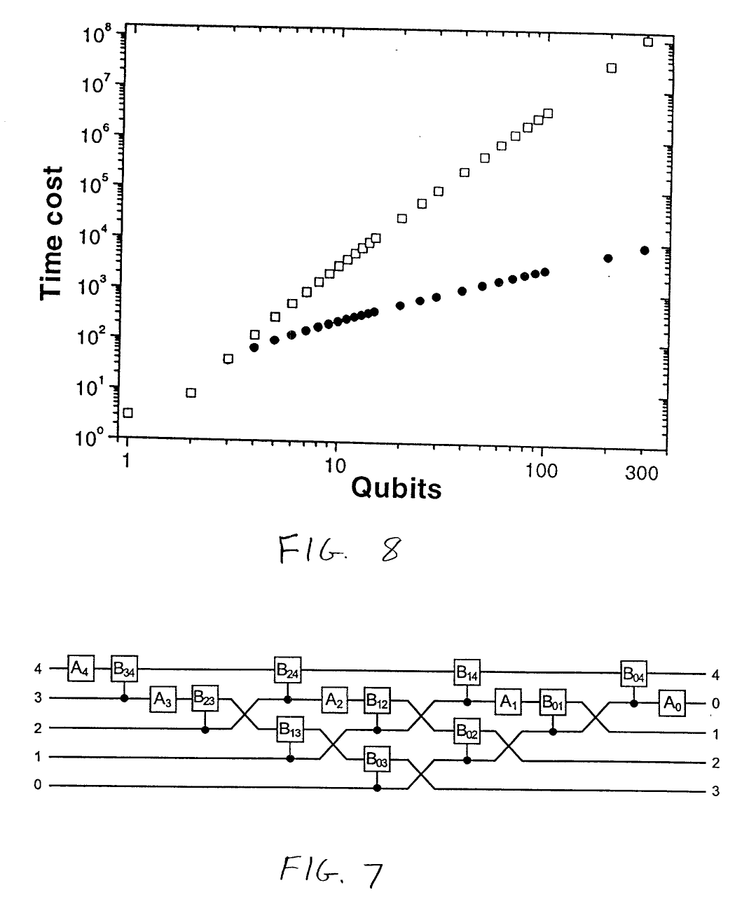

The networks having the construction of FIG. 6 can be further shortened by permuting the logical operations to reduce the number of swaps and to maximize parallel performance of operations. FIG. 7 illustrates QFT₅ after further optimization.

Minimizing the time required for the network corresponds for solving a constrained optimization problem and has many similarities to the problem of placement occurring in VLSI related technologies. In placement, one seeks to arrange the components of a classical circuit in a way minimizing the length of interconnecting wires and area of the circuit. Heuristitics like simulated annealing or tabu search are known to give good results for such problems. The problem of optimizing a network for a quantum calculation is very similar but with the additional complication that reordering two logical operations at a given location in a circuit will change the sequence and possibly the number of swaps needed at all further points in this circuit. The file “anneal.txt” in the CD appendix contains a listing for a program that performs simulated annealing to optimize a network for a QFTn. As this is a heuristic process, the program will not provide optimal solutions but solutions which are close to the optimal solution.

Although the invention has been described with reference to particular embodiments of quantum computers and a particular algorithm, the description is only an example of the invention's application and should not be taken as a limitation. Although much of the above disclosure was directed at examples implementing quantum Fourier transforms (QFTs), other quantum computing procedures can similarly benefit from the procedures described. Additionally, although quantum computations where disclosed for a system employing a linear arrangement of qubits, embodiments of the invention are also applicable to other quantum computing architectures including but not limited to two-dimensional arrays of qubits with nearest neighbor interactions. Various other adaptations and combinations of features of the embodiments disclosed are within the scope of the invention as defined by the following claims.

I claim:

1. A method for reducing required coherence time for a quantum computation, comprising:
constructing a first series of operations on qubits that perform the quantum computation; and
constructing a second series of operations from the first series by changing an execution order of the commuting operations to reduce the time required for a quantum computing device to complete the second series of operations.

2. The method of claim 1, wherein constructing the second series of operations from the first series of operations comprises changing the execution order of the commuting operations in the first series so that two or more operations are performed simultaneously in the second series.

3. The method of claim 2, wherein the first series of operations includes a swap operation that changes a first qubit and a second qubit from having respectively a first state and a second state to having respectively the second state and the first state.

4. The method of claim 3, wherein:
changing the order of the commuting operations eliminates a need for the swap operation; and
constructing the second series further comprises omitting the swap operation from the second series so that execution of the second series of operations performs the quantum calculation faster than executing the first series of operation.

5. The method of claim 1, wherein
the first series of operations includes a swap operation that changes a first qubit and a second qubit from having respectively a first state and a second state to having respectively the second state and the first state; and
changing the order of the commuting operations in the first series eliminates a need for the swap operation; and
constructing the second series of operations further comprises omitting the swap operation from the second series so that execution of the second series of operations performs the quantum calculation faster than executing the first series of operation.

6. A method for performing a swap operation in a quantum computing device, the method comprising:
performing operations from a sequence of operations; and
simultaneously performing two of the operations that commute.

7. The method of claim 6, wherein performing the sequence of operations comprises:
simultaneously performing a first operation Zᵣ(π/2) on a qubit r and a second operation Zₛ(π/2) on a qubit s;
sequentially performing third operation Xₛ(π/2) on the qubit s, a fourth operation Zₛ(π/2) on the qubit s, and a fifth operation CPᵣₛ(π/2) on the qubits r and s;
simultaneously performing a sixth operation Xₛ(π/2) on the qubit s and a seventh operation Xᵣ(π/2) on the qubit r;
sequentially performing eighth operation Zᵣ(π/2) on the qubit r, and a ninth operation CPᵣₛ(π/2) on the qubits r and s;
simultaneously performing a tenth operation Xᵣ(π/2) on a qubit r and an eleventh operation Zₛ(π/2) on a qubit s;
sequentially performing twelfth operation Xₛ(π/2) on the qubit s, a thirteenth operation Zₛ(π/2) on the qubit s, a fourteenth operation CPᵣₛ(π/2) on the qubits r and s, and a sixteenth operation Xₛ(π/2).

8. The method of claim 7, wherein the third, sixth, seventh, tenth, twelfth, and sixteenth operations act on the two states of the respective qubits according to the following equation
$$X ( θ ) = {ⅇ}^{\frac{- ⅈ {σ}_{x} θ}{2}} .$$

9. The method of claim 7, wherein the first, second, fourth, eighth, eleventh, and thirteenth operations act on the two states of the respective qubits according to the following equation
$$Z ( φ ) = {ⅇ}^{\frac{- ⅈ {σ}_{z} φ}{2}} .$$

10. The method of claim 6, wherein the fifth, ninth, and fourteenth operations the four combined states of the qubits r and s according to the following equation
$$CP ( ς ) = {ⅇ}^{\frac{- ⅈ {σ}_{z} ⊗ {σ}_{z} ς}{2}}$$
